(19) United States
(12) Patent Application Publication
(10) Pub. No.: US 2013/0130439 A1
(43) Pub. Date: May 23, 2013

(54) FORMED METALLIC HEAT SINK SUBSTRATE, CIRCUIT SYSTEM, AND FABRICATION METHODS

(71) Applicant: Peter J. HOPPER, San Jose, CA (US)

(72) Inventor: Peter J. HOPPER, San Jose, CA (US)

(73) Assignee: TEXAS INSTRUMENTS INCORPORATED, Dallas, TX (US)

(21) Appl. No.: 13/301,696

(22) Filed: Nov. 21, 2011

(51) Int. Cl. H01L 21/50; F28F 7/00

(52) U.S. Cl. 438/106; 165/185; 257/E21.499

(57) ABSTRACT

A thermally conductive substrate for suitable for use as a three dimensional heat sink for electrical device systems. The substrate comprises a base element with a cavity comprising a recessed device mounting site. Associated device systems include one or more devices arranged in the three dimensional heat sink which can be encapsulated into a device package and associated construction methodologies.

### TECHNICAL FIELD

The invention described herein relates generally to semiconductor device mounting substrates and associated devices. In particular the invention realties to multi-device heat sinks suitable for use as substrates for mounting heterogeneous devices on a common three dimensional heat sink. The invention relates to the construction of high density heterogeneous circuit packages and structures formed substrates and particular electrically conductive substrates used as supports for integrated circuit fabrication. In particular, the invention relates to mounting substrates and packages suitable for supporting power devices on the same substrate as other types of devices. Also, the invention is directed to cost effective and heat tolerant copper integrated circuit substrates and methods of construction. The principles herein are also applicable to other semiconductor packages and devices.

### BACKGROUND

Existing packaging solutions for manufacturing electronic devices use a number of packaging technologies. Such devices can use so-called embedded devices that can become quite hot during usage. One way that such devices deal with the heat issues is form a leadless lead frame package that exposes a bottom portion of the packaged die to the ambient environment enabling the heat to be bled off by the ambient. Alternatively, a bottom portion of the die can be exposed and then contacted with a circuit board enabling it to bleed off heat directly into the board. This is especially important for power type devices, which commonly generate large amounts of heat. Commonly, in order to achieve such a configuration packages use a leadless lead frame to achieve the desired properties. In such an implementation wire bonds are used to electrically connect input/output (I/O) connectors of an integrated circuit (IC) device with external leads. But package heat limits the type and concentration of such devices on a substrate. Also, due to the high heat, different types of devices must be separated by significant distances. This leads to many performance issues resulting from parasitic effects. Typically, such issues are dealt with by packaging only similar devices on a single die and then packaging it individually and then mating up heterogeneous circuit devices on the BCB. Although such packaging works well for a large range of devices, it is subject to some limitations.

For these and other reasons, an improved design of such packages would be helpful in the industry.

### SUMMARY OF THE INVENTION

In accordance with the principles of the present invention, package configurations and fabrication methodologies are disclosed.

In one embodiment an invention describes a conductive substrate suitable for the mounting of electrical devices. In one embodiment, the substrate comprises a conductive base element comprising a conductive material. The base element includes a cavity comprising a recessed device mounting site formed on the base element. Embodiments of such recessed device mounting sites are suitable for the holding of an electrical device. Importantly, the spacing between such recessed device mounting sites can be very small.

In another embodiment, the invention describes a conductive substrate having electrical devices mounted thereon forming a device package which can be an electrical device system package or device, for example, an IC or other electrical system. In one such embodiment, a heat sink comprising a recessed device mounting sites on a base element comprises an electrical device arranged in the recessed device mounting site. In many embodiments such a device is further in thermal communication with the base element at a bottom surface of the base element. And also in thermal communication with a sidewall of the recessed device mounting site thereby forming a three-dimensional heat sink for the electrical device. Such an electrical device system can also comprise an IC system. Such electrical device systems can comprise a group of many different heterogeneous electrical devices formed on a common heat sink wherein the devices can be electrically connected with one another on the common heat sink. Such assembled electrical device systems can be encapsulated to form individual device packages. In one embodiment, the electrical device systems can be formed on a wafer scale encapsulated and singulated to form many individual packages.

In another embodiment a method of forming an electrical device system having a three dimensional heat sink is described. One such method includes operations of forming a recessed device mounting site on a base element which can, and typically does, comprise a conductive material. And can include operations of arranging an electrical device in the recessed device mounting sites, arranging a protective layer on the base element; and forming an electrical interconnect that passes through the protective layer such that the interconnect is in at least one thermal and electrical communication with at least one of the device and the base element. Such a device can be formed into an electrical device system including IC's.

Such an electrical device system can comprise a group of many different heterogeneous electrical devices formed on a common heat sink wherein the devices can be electrically connected with one another on the common heat sink. Such assembled electrical device systems can be encapsulated to form individual device packages. In one embodiment, the electrical device systems can be formed on a wafer scale encapsulated and singulated to form many individual packages.

These and other aspects of the present invention are described in greater detail in the following detailed description of the drawings set forth hereinbelow.

### BRIEF DESCRIPTION OF THE DRAWINGS

The following detailed description will be more readily understood in conjunction with the accompanying drawings, in which:

FIG. 1 is a section view of a portion of a conductive base element suitable for use in accordance with the principles of the present invention.

FIG. 2 is a section view of the conductive base element with a first mask patterned on the base element.

FIG. 3(a) is a section view of the conductive base element with metal plated between openings in the first mask in accordance with an embodiment of the invention.

FIG. 3(b) is a plan view of the plated substrate shown in FIG. 3(a).

FIG. 4 is a section view of the plated conductive base element with the mask removed exposing the recessed device mounting sites in accordance with an embodiment of the invention.

FIG. 5 is a section view of the plated conductive base element with the mask removed exposing the recessed device mounting sites in accordance with an embodiment of the invention.

FIG. 6(a) is a section view of the base element with a third mask having openings arranged to expose the recessed device mounting sites in accordance with an embodiment of the invention.

FIGS. 6(b)-6(c) are figurative section views of one embodiment of a vertical power transistor and an arrangement of the device in a recessed device mounting sites in accordance with an embodiment of the invention.

FIGS. 7(a)-7(b) are section views of the substrates with devices mounted with the recessed device mounting sites and having an overlying fourth mask layer having vias arranged to selectively expose the underlying devices and portions of the base element in accordance with selected embodiments of the invention.

FIGS. 8(a)-8(d) are section views of the substrate embodiments and associated process flows enabling the formation of via fills arranged to enable one or both thermal heat transfer or conduction paths and electrical conduction paths in accordance with selected embodiments of the invention.

FIG. 8(e) is section views of a substrate embodiment showing electrical and/or thermal conduction paths between devices formed on the base element in accordance with selected embodiments of the invention.

FIGS. 9(a)-9(b) are section and plan views of device embodiments showing some example interconnect embodiments showing a few exemplar electrical connections between example devices in accordance with the principles of the present invention.

FIG. 10(a)-10(d) are flow diagrams depicting a few example method embodiments for constructing devices and substrates in accordance with the principles of the present invention.

It is to be understood that, in the drawings, like reference numerals designate like structural elements. Also, it is understood that the depictions in the Figures are not necessarily to scale.

### DETAILED DESCRIPTION OF THE DRAWINGS

The present invention has been particularly shown and described with respect to certain embodiments and specific features thereof. The embodiments set forth herein below are to be taken as illustrative rather than limiting. It should be readily apparent to those of ordinary skill in the art that various changes and modifications in form and detail may be made without departing from the spirit and scope of the invention.

The following language describes various embodiments of a wafer scale invention and associated methods of fabrication (i.e., wafer scale comprising apparatus subject to wafer scale micro-processing such as used in semiconductor wafer fabrication and processing). Thus, the substrates and device systems used with this invention can comprise very small heat sinks and multi-device substrates suitable for use semiconductor devices and associated construction methodologies. “Wafer scale” is used to draw a distinction between larger individual die systems which typically comprise arrangements of small die on a larger distinct substrate. Generally, such prior art die are all fabricated and then singulated and then integrated into a circuit board. The present invention is much smaller and capable of supporting numerous small systems of heterogeneous devices on single substrates (e.g., a single heat sink). Also described is a related substrate and integrated circuit device suitable for use in large scale wafer level fabrication of heterogeneous circuit elements and devices on a single substrate. Such an approach is extremely valuable because, using wafer level processes, minimum electrical interconnect distances between electrical devices and elements can be reduces to a level that is many times less than that achievable with state of the art PCB mounting and fabrication processes. These and other advantages are enjoyed by embodiments of the invention.

In particular, the disclosed embodiments comprise a thermally conductive substrate that includes recessed device mounting sites suitable for the arrangement of circuit elements thereon and the inclusion of added thermal heat spreaders to provide three dimensional heat sinking capacity and also enable the integration of such circuit elements into large scale structures comprising many such circuit structures sharing the common conductive heat sinking substrate. Such a substrate enables wafer level systems integration of, among other things, heterogeneous circuit elements and can enable large scale integration of several different types of electrical elements (e.g., flash memory and power devices as well as nearly all other types of devices) on a single same substrate and further provide very close physical proximity between the devices (substantially reducing parasitic and resistance related electrical effects) and offers a compact highly effective heat sink for all of the devices enabling effective high density circuit construction.

The inventors specifically note that the principles of the invention are not limited to the above implementations, but cover a number of related devices as readily apparent to those of ordinary skill.

In one implementation, the inventors propose a thermally conductive substrate operating as a systems integration platform.

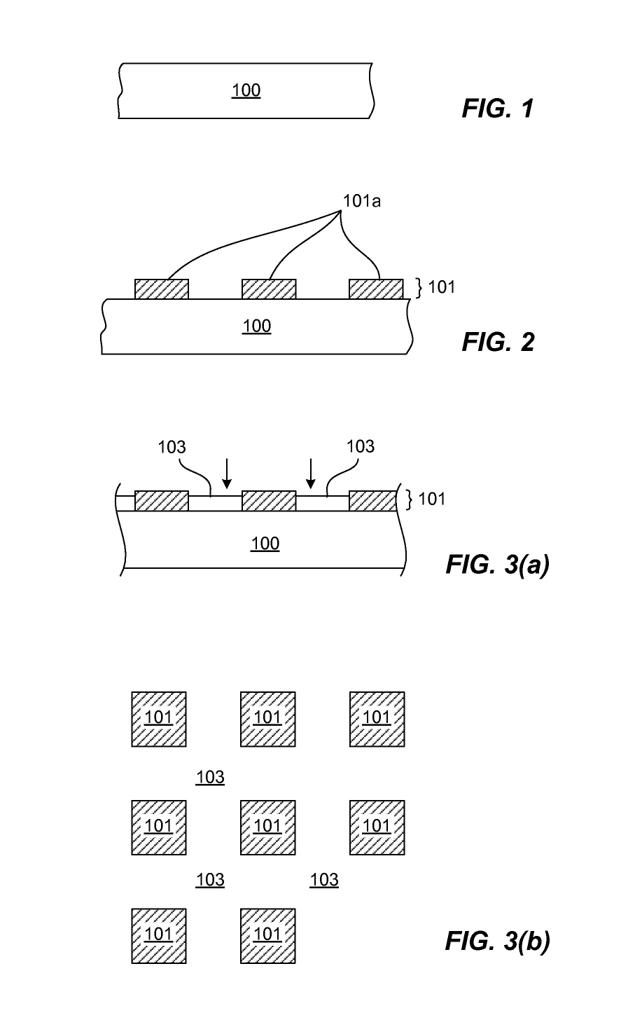

FIG. 1 illustrates an embodiment of a suitable substrate or base element in readiness for further processing in accordance with an aspect of the invention. Such a substrate although suitable for comprising a separate product, finds wide applicability as a substrate for an electrical device system.

In this implementation, the substrate 100 comprises a thermally conductive material. In one common implementation, a thin copper sheet of material is used. However, other materials, alloys, or laminated conductive materials can be used. In another implementation, a laminate could be used. For example, a thick diamond layer can be chemical vapor deposited onto a mechanically resilient support (e.g., silicon). However, such embodiments are not limiting and the invention contemplates the use of thermally conductive composite materials and also the formation of metals on a wide range of base support materials (e.g., metal, composite materials, etc.). This substrate 100 serves as a heat sink for circuit devices and elements formed thereon. The substrate can be made of copper and will be commonly be constructed in a thickness ranging from about 500 microns (μm, 10⁻⁶ meters) to about 25 mm (millimeters) with a preferred thickness being about 1 mm thick. In preferred embodiments, such substrates will be shaped and sized like silicon wafers at dimensions on the order of 25 mm, 50 mm, 100 mm 200 mm, 300 mm, and larger. It is anticipated that, due to the greater thickness and strength of a metal substrate, much larger sizes can be used. It is pointed out that these sizes and shapes are merely examples and should not be construed as limiting the invention. In use, the substrate can be defined as having an array of die fabrication sites some being as small as 2 mm by 2 mm or in some cases even smaller. Each site configured to support a completed electrical device system (in one implementation an IC). It is specifically pointed out that these dimensions are useful examples and not intended to be limiting. The dimensions are not intended to limit the embodiments of the invention. They are simply included to provide a few useful examples.

The substrate is then processed to form recessed device mounting sites suitable for the mounting of electrical elements. Such can comprise building up raised structures. Alternatively, the recesses can formed in the substrate by removing portions of the substrate or, in another alternative, adding a second substrate comprising a series of raised portions that can define the recess when mounted on a first substrate.

FIG. 2 is a section view of a substrate having a patterned masking layer 101 arranged thereon. In this implementation, the masking layer comprises a layer 101 of removable photoimageable material (e.g., a photoresist material) after exposure to an appropriate light source and developed to attain the desired pattern after the excess material is removed. Where a photoresist is used, example resists can comprise positive or negative photoresists depending on cost or performance needs of the system. For example, the layer of photoresist material can spin coated (or roll coating or slit coating or another application process). The layer 101 can generally range from about 50 μm to about several mm with one preferred embodiment being about 100 μm thick.

In specific examples, many different phororesist materials can be used to form a suitable photoresist pattern 101. Materials can include, but are not limited to materials like AZ 40XT and AZ 125nXT manufactured by AZ Electronic Materials, headquartered at Stockley Park in the United Kindom. Other removable photoresist materials can be used as well. In another embodiment, a novolac type material is an attractive candidate. The resist layer 101 is selectively irradiated to produce a desired exposure pattern having features 101a. For example, irradiating the resist layer 101 through a shadow mask pattern and then developing the layer can produce the desired pattern.

Generally, the masking features 101a can be of any size, in one attractive embodiment the features are only on the order of about 1-2 μm mm wide. In general, the features 101a can be sized and shape to accommodate the electrical elements that will later be placed on at least some of the sites defined by the features 101a. The features 101a define a pattern in the intervening space (an example of which is shown in the plan view FIG. 3(a)). Such can be of any size but on the order of microns if desired. Such narrow structures enhancing device density. But can also be on the order of one or more millimeters wide. It is very important that the reader understand that these are example dimensions only. A wide range of other dimensions are possible and subject to the needs of the designers.

With reference to FIG. 3(a) another section view of the patterned substrate 100/101 is depicted. After formation of the patterned removable masking layer 101, the exposed deposition sites 102 are processed to add conductive material to the substrate 100 forming raised portions 103 of the surface. These raised portions 103 define a feature recessed from the built-up top source of the base substrate 100. Thus, the raised portions 103 define a cavity (recessed device mounting site 105) in the built-up top surface of the base element 100. The unmasked regions 102 can be built up using a number of approaches (e.g., deposition, electroplating, as well as other modes). In one example, the exposed regions 102 are simply electroplated to build up the region. The idea being that the added conductive material forms newly raised portions 103 of conductive material. In one particularly advantageous embodiment, the metal 103 is the same as that of the substrate 100. For example, using a copper substrate 100, additional copper material can be plated onto the copper substrate 100 at sites 102 until it reaches a desired thickness which can be any height. In one embodiment, such thicknesses can range from about 50 μm to about 200 μm with one preferred embodiment comprising a raised portion about 100 μm tall. It is pointed out that these are examples only. A wide range of other thicknesses can be used. For example, the height can be tall enough such that it is taller than a device to be placed in a site defined by the raised portions. Although it is believed that electroplating is the most cost effective mode, other deposition methods can be used. It is pointed out that in most implementations the added conductive material 103 is the same as that of the substrate 100. However, any other compatible and thermally conductive material can be disposed upon the substrate 100 to form the raised portions.

FIG. 3(b) is a plan view of one embodiment of a patterned substrate 100/101 after plating of the conductive material 103. The raised portions 103 are shown forming walls around the photoresist structures 101a. Here, the photoresist structures 103 are arranged as an array of isolated photoresist “islands”. But, many other structures can and will be formed in accordance with the principles of the present invention. Examples include, but not limited to, long rows of photoresist, non-rectangular configurations, and in fact can comprise an unlimited arrangement of other configurations.

It is specifically pointed out that such recessed device mounting sites (e.g., 105) can be formed using other approaches. In one example, cavities can be selectively etched into the base substrate at various locations to define a set of recessed device mounting sites having raised sidewalls. Many different methods of forming such recessed device mounting sites can be used, masking with selective etching in the exposed regions wet etching, plasma etching as well and many other processes can be used. Additionally, a second substrate having a pattern of holes formed in the second substrate can be mounted or otherwise disposed on the base element. Open portions of the holes defining the recesses of the recessed device mounting sites when the second substrate is mounted onto the base element. The sidewalls of the holes defining sidewalls for the recessed device mounting sites. For example, in one embodiment (of which many others can be used) a copper base substrate can be used. A copper second substrate can be treated with a layer of solder paste and then positioned on the base element and subject to reflow to form the new substrate. In another approach, the copper base substrate can be treated with a layer of solder paste and then the second layer is positioned on the base element and subject to reflow to form the new substrate. Additionally, devices can be mounted to the recessed device mounting sites and then a single reflow process can be used to unify the devices and base element with the second substrate. In another approach, a pair of reflow process can be used to affix the second substrate and then the devices in another reflow step. Or in another alternative, the solder past can be selectively applied to the base element such that there is no solder paste in the future exposed recessed device mounting sites. In still other approaches, no solder paste is used at all and other means of joining the second substrate with the base substrate can be used.

In an approach using a second substrate, the second substrate is generally as thick as (or thicker than) as the devices and elements to be used in the system. Additionally, where an etched recess approach is used several depths of recesses could be etched. In another approach, the two processes could be used together. In one such embodiment, if devices having different heights are to be used, the base substrate could have etched portions to be used with taller devices while shorter devices could be arranged in the other recessed device mounting sites that are not etched as deeply or not etched at all. In one embodiment, the thickness of the second substrate can range from about 50 μm to about 2000 μm with one preferred embodiment being about 100 μm thick. Such can be mounted and/or arranged on a lead frame of other configuration.

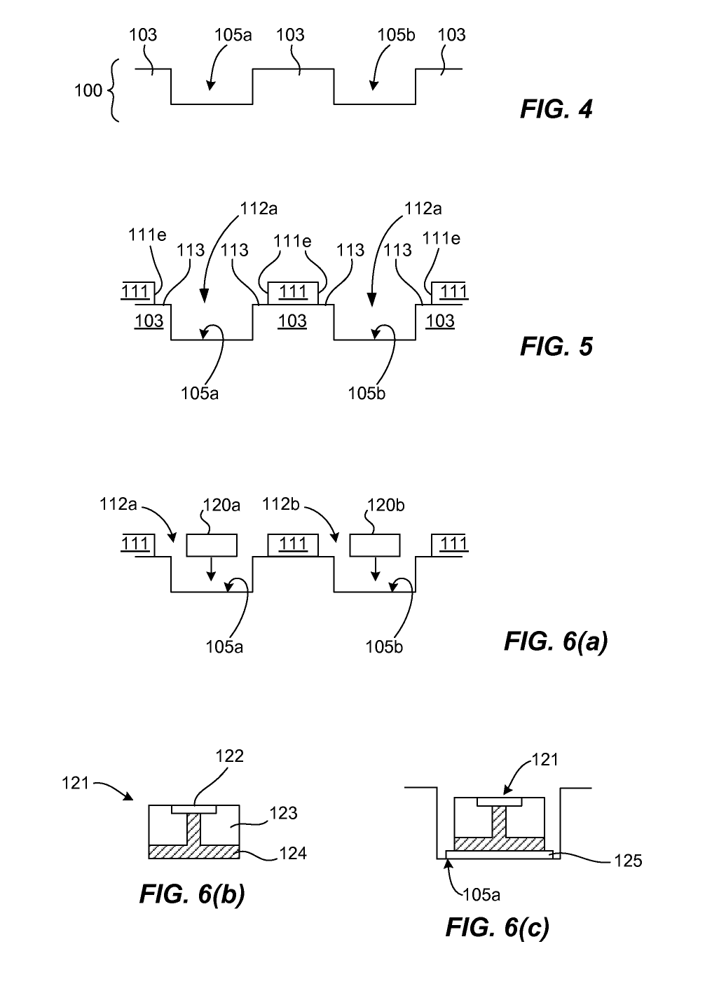

FIG. 4 is a section view of the substrate after the photoresist layer has been removed and only the built up raised portions 103 remain on the substrate 100. The raised portion 103 can form walls that define recessed device mounting sites 105 between the raised portions 103 of the substrate 100. Here, two such sites 105a, 105b are used for example. It is possible that the substrate 100 only have one recess 105, but more typically includes many such recessed device mounting sites 105 arranged over various portions of the substrate 100 surface. The present example is described in terms exemplary recessed sites 105a, 105b serving as a convenient explanatory tool.

In an alternative embodiment, recesses can be formed in the substrate 100 by removing portions of the substrate. For example, selective etching of the surface can be used. In one implementation, the surface can be masked revealing only the portions to be removed, then etching or other processes suitable for removing material are used to form one or more recessed device mounting sites. The sites are made deep enough so that later mounted devices fit into the recessed sites. This process has the advantage of enabling recesses to be formed having different depths with relative ease. In one embodiment, such recesses can range from about 50 μm to about 200 μm deep with one preferred embodiment comprising a recess about 100 μm deep.

With reference now to FIG. 5, a portion of a substrate 100 having the recessed device mounting sites 105a, 105b and the raised portions 103 of FIG. 4, is shown with an optional second mask 111 formed thereon. Although frequently this mask can be dispensed with using mask layers (120, 140, etc.) discussed later in the specification. One implementation used the second mask 111 because it is useful to provide a more easily etchable material than later masks. Such a mask can have good etchability using SF₆ and inductively coupled plasma (ICP) etching. This can enable higher process speeds. In one embodiment, the second mask 111 comprises a permanent photoresist (e.g., a photoimageable epoxy). As before, the second mask 111 is processed as described above (selective irradiation, development, and removal of the desired portions) thereby forming the desired mask pattern on the substrate. Here, the mask 111 is shown exposing the recessed device mounting sites 105a, 105b. Here, the openings 112a, 112b are in substantial alignment with the recessed device mounting sites 105a, 105b. Additionally, in this implementation, mask features 111 define setbacks in the openings 112a, 112b arranged to expose a portion 113 of the upper surface of the raised features 103. Accordingly, an edge 111e of a photoresist feature 111 is set back 113 from the edge 103e of the raised portion 103 of the substrate 100. Thus, while the photoresist pattern includes openings 112 in registry with associated recesses 105 the setbacks can also expose upper surfaces 113 of the raised portions 103. Also, in some embodiments, the invention contemplated configurations where the edges 103e, 111e can be aligned as well.

As before, the second mask layer 111 can comprise positive or negative photoresists depending on cost or performance needs of the system. Such can be applied using a wide range of application methodologies including, but not limited to spin coating, roll coating, or slit coating as well as other processes. In one embodiment, the second mask 111 can have a thickness ranging from about 1 μm to about 5 μm thick. Using such an approach selective irradiation, development, and lift off is performed to selectively pattern the mask 111. It is pointed out that the mask 111 can also be formed of other insulative or dielectric materials. However, the invention contemplates that photoimageble materials and processes provide the most efficient and cost effective approach.

Additionally, mask 111 can be formed using any of a number of photoresist materials or epoxies. Permanent or removable photoresist materials can be used. For example, PBO (Zylon) could be used in another example, SU8 sold by MicroChem of Dresden, Germany can be used, as can BCB and KMPR1000 supplied by Hitachi. Also suitable are polyimide photoresist materials, photoresist materials, as well as others. Some desirable features in second mask are that it have relatively good adhesion to the substrate material 100 (e.g., copper), high breakdown voltage (e.g., at least about 300V), high Young's modulus (above 3, or higher?), elasticicity sufficient to resist cracking during temperature cycling, high thermal resistance (e.g., a breakdown temperature of at least 300° C.), a dielectric constant of in the range of about 3 to 4. It is pointed out that such material properties are preferred, not mandatory, with a wide range of lesser properties still forming adequate second photoresist layers 111.

With reference now to FIGS. 5 and 6(a), once the openings 112 are made in the second mask 111 electrical devices 120a, 120b are disposed within the recessed device mounting sites 105 (for example the depicted 105a, 105b). Typically, a preformed device or group of devices can be arranged within the recesses 105. However it is contemplated that devices can also be fabricated directly within the recesses using wafer processing techniques.

Importantly, the devices 120a, 120b can be vastly different in functionality. Such mating of heterogeneous devices is not possible in the prior art. In the prior art in small single wafer implementations, typically all of the devices are the same, all flash memory, all power devices, and so on. These devices are then mated up with separate heat sinks and then mounted to a PCB as individual IC's. Although useful for a number of purposes, they do not have the ability to make very small, very dense, heterogeneous circuit structures combinable on a single small profile IC. The minimum electrical interconnect distances between electrical devices and elements on a PCB substrate is at least an order of magnitude greater than that which can be achieved using a wafer level semiconductor process. This can be a significant limitation.

This invention enables the formation and/or placement of such heterogeneous devices in very close proximity on a common three-dimensional heat sink. Thus, very short electrical connections between devices can be made. For example, using a PCB implementation and taking into consideration mold cap and sidewall thicknesses for individual die, device to device interconnect distances are on the order of at least 1 or more mm. Whereas, in accordance with the principles of the present invention, distances of as little as 100 μm or less are possible. Thus, in general PCB interconnections due to their longer distances suffer from increased parasitic effects relative to the inventive devices, examples of which, are disclosed herein. Additionally, the claimed invention enables all of the heterogeneous components to be cooled by a three dimensional heat drawing heat from the bottom and the sidewalls of the recessed device mounting sites and other portions of the circuit elements which is believed to provide much increased thermal performance.

The range of devices that can be used with the invention are quite broad, including both passive and active elements, arrays of such elements, as well as heterogeneous combinations of such devices. Examples can include, but are not limited to flash memory elements, power convertors, power devices in general (e.g., vertical power transistors), transformers, rectifiers, any of a number of transducers, sensors, actuators, MEMS devices, or a wide range of other circuit elements or systems. Small integrated circuits (IC) can also be arranged in the recess. In one example implementation, a larger recess 105 (in one example are recess on the order of 2 mm×2 mm) can mount an IC device having substantial numbers of elements and substantial functionality. But in practice, the size of recesses and the types and combinations of devices and elements that can be arranged in the recesses is essentially limitless.

In one implementation, a solder paste or other thermally conductive material can be used to couple the electrical elements 120a, 120b within the associated recesses 105a, 105b. In the case of a solder material, a reflow process is used to affix the elements 120a, 120b in the recesses. For example, a layer of solder paste can be deposited onto a surface of the recess 105. An element 120a, 120b is then placed on the solder paste within the associated recess 105a, 105b. Elements can be placed at high rate of speed using a pick-and-place tool such as is available from Semiconductor Equipment Corporation as well as companies like EV Group. Such attachment can also be done in accordance with the direction above with respect to the two substrate embodiments.

FIG. 6(b) shows and example of one such device (e.g., such as 120a, 120b), a vertical power transistor device 121. In common practice, such a device is mounted on a separate chip package with a dedicated heat sink. This package is affixed to a PCB with outer components. This leads to somewhat longer electrical interconnection pathways to other PCB mounted components. Drastically so when compared with wafer scaled interconnect structure. Although the invention is not limited to such, this device will be used as an example useful for illustrating further principles of the invention. In this embodiment, the vertical transistor 121 comprises a source 122, gate 123, and drain 124. It is pointed out that these devices can be very small, on the order of 150 μm by 150 μm. The indicated orientation and type of transistor can also be varied.

In this embodiment, shown in FIG. 6(c), the device 121 is mounted using a solder paste 125. In one example process, the solder paste 125 can be reflowed 10-20 minutes at a reflow temperature of about 26° C.° to adhere the device 121 to a recess 105. In some embodiments, the solder paste 125 can be disposed on a bottom surface of the device 121 or alternatively on the upper surface of the recess 105. The device is placed within the recess and then reflowed. In another approach, the device itself can be fabricated within the recess.

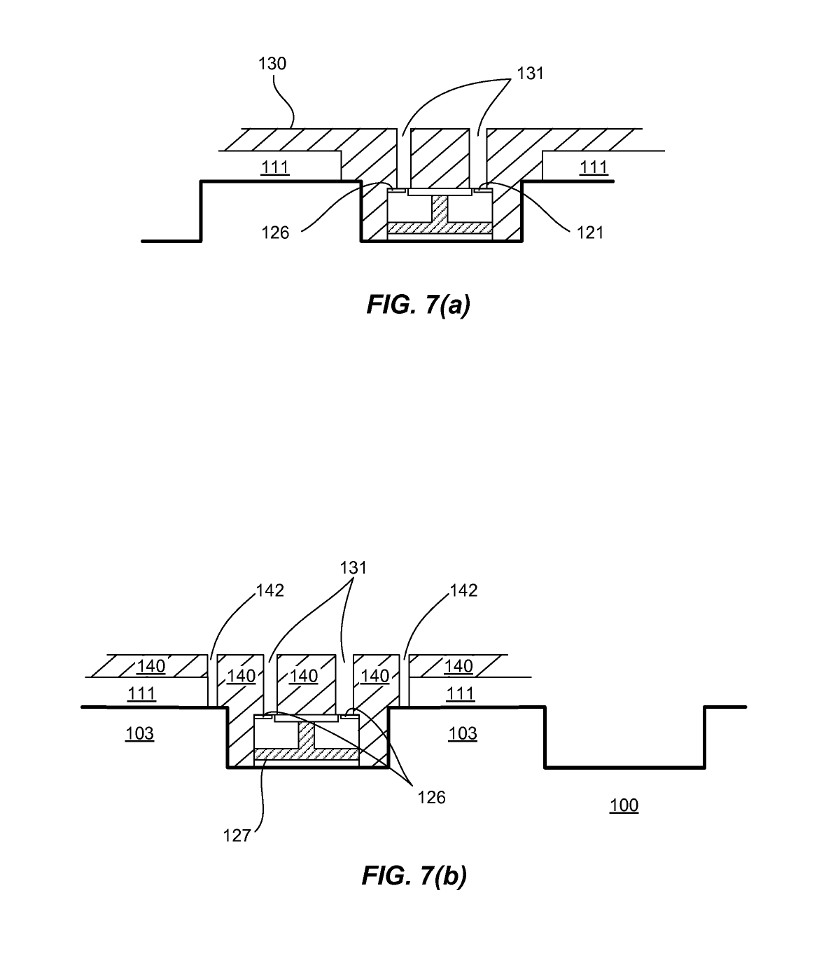

With reference to FIG. 7(a), a third protective mask layer 130 is disposed on the surface. As before, the protective layer 130 is patterned. In one approach another photoimageable material and process can be used. Alternatively, an insulating or dielectric layer can be used. In one example a permanent photoresist material can be used. In this embodiment, the protective layer 130 includes a first set vias 131 (or via) arranged to expose a portion of the underlying electrical element 121. In some cases the via 131 is intended to contact the element 121 to transfer thermal energy (not electrical). In others, the via 131 is intended to facilitate an electrical connection with the element 121. In the depicted approach an electrical contact is desired, in this example the via 131 exposes an electrical contact 126 of the depicted vertical power transistor device 121. Such a connection can enable one or both of an electrical connection with the device and/or a thermal heat transfer path away from the device 121. In particular, a via can be directed to expose a portion of the underlying component without exposing an electrical contact.

Again, the third mask layer 130 can comprise a permanent photoresist that can be the same as that of the second mask 111 or other photoresist material. As before, the third mask 130 is selectively exposed, developed and the desired portions removed to form the vias 131. Much the same as the second mask layer 111, the third mask 130 can be applied using a wide range of techniques materials essentially the same or similar to that of second layer 111.

In one embodiment, the third mask layer 130 can have a thickness ranging from about 3 μm to about several 100 μm thick with one preferred embodiment being about 100 μm thick. The same types of photoresist and photoimageable materials discussed above can be used here. Also as before, other insulating or dielectric material layers can be used to define the mask 130. Such can be processed to generate the desired openings and patterns as well. For example, etching, selectively patterned deposition, and so on. As before, it is believed that photoimageble materials and processes are just the most efficient and cost effective approach.

An alternative approach is discussed with respect to FIG. 7(b) which illustrates a different configuration. In this embodiment, the third mask 140 is disposed differently on the surface and over electrical element 127. In one particular embodiment the electrical element 127 can be a standard power transistor (i.e., not a vertical power transistor). As before, the layer 140 is patterned. This time, the pattern includes a different arrangement of vias 141, 142 arranged in the layer 140. In this embodiment, some vias 141 are arranged to expose a portion of the device 121. Whereas other vias 142 enable thermal communication with the underlying raised portions 103.

In one embodiment, the vias 141 can be used to facilitate electrical connection with the device 127. Alternatively, the via 141 is merely configured to provide a heat flow path that can enable heat to flow away from the device 127. Additionally, via 141 can be supplemented (or indeed replaced by) a second via 142 (or set of vias) formed in the third layer 140. The via 142 enables thermal communication with the underlying raised portions 103 this providing another heat removal pathway. As in the embodiment above, the patterned third layer 140 can be formed just as the third layer 130 above.

The third layer 140 can have thicknesses in the same range as mask layer 130 discussed above with one preferred embodiment being about 100 μm thick. The same types of photoresist and photoimageable materials or other insulating or dielectric materials discussed above can be used here as well as long as there is compatibility with the second layer 111. It is again pointed out that the present inventions are not limited to use with vertical and other power transistor but can be broadly applied to a wide ranged of devices (generally any passive or active device, to include, but are not limited to memory devices, power devices and transistors, transducers, sensors, actuators, MEMS devices, IC's in general, and a wide range of other circuit elements or systems. As before, a core idea in some embodiments is the integration large scale arrays of heterogeneous components on a common substrate (here, a three dimensional heat sink).

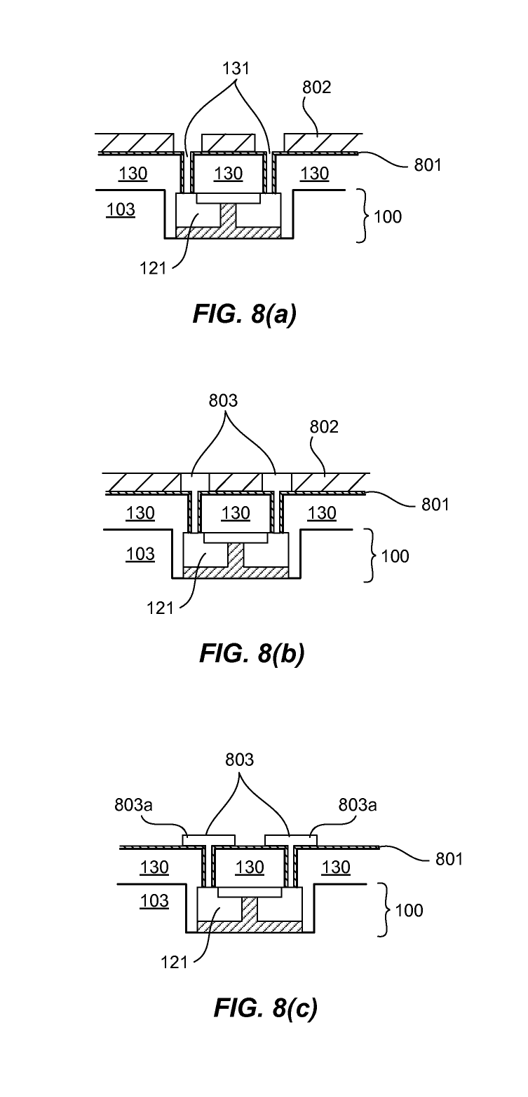

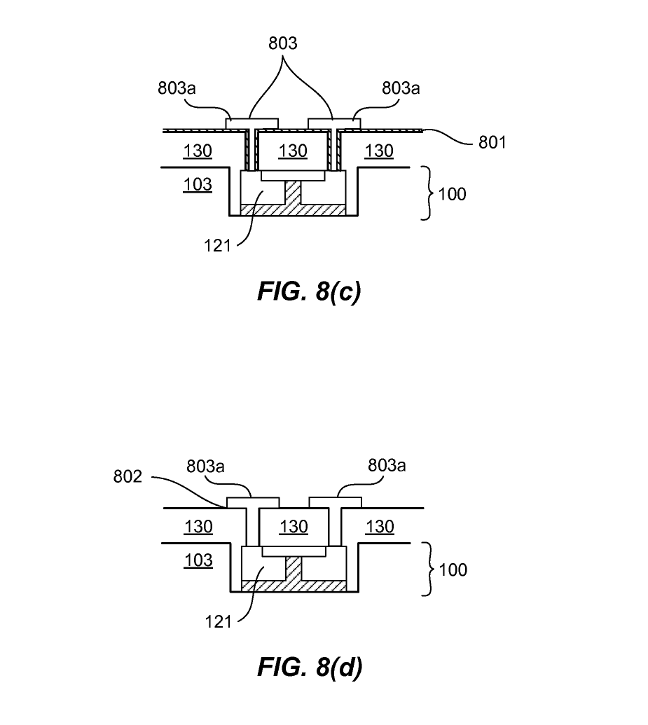

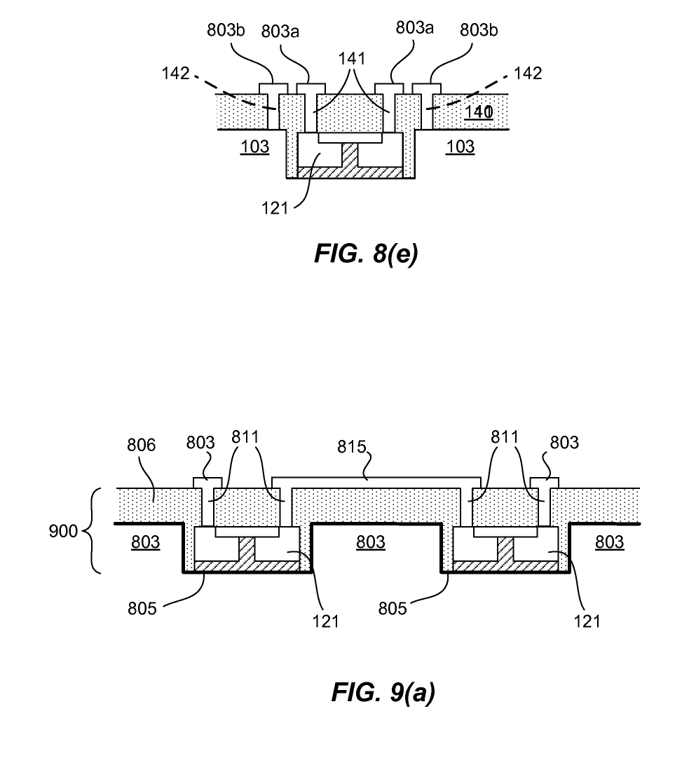

FIG. 8(a) is a view of the substrate of FIG. 7(a) after further processing. In one embodiment, a seed layer 801 is arranged on the surface. Such a layer can comprise a single layer of material that is thermally conductive, electrically conductive, or both. For example, layers of copper (Cu), aluminum (Al), titanium (Ti), nickel (Ni), gold (Au), alloys, as well as others can be used. In one approach a Ti seed layer 801 is used. It can be thin. Perhaps only about 100 Å thick. Other embodiments ranging from about 50-4000 Å can also be used. In another embodiment, a number of metals can be used together to form a multi-layered structure. For example a seed layer 801 can comprise a tri-layer of titanium, copper, and then titanium. A first Ti layer can be formed of any desired thickness (in one example, about 300 Å thick). A second Cu layer can be formed on the first Ti layer. This layer can be formed of any desired thickness (in one example, about 2000 Å thick). On top, a second Ti layer can be formed of any desired thickness (in one example, about 300 Å thick). Thus, in this embodiment a composite multi-layer 801 of about 0.03 μm thick can be formed. Example processes can comprise a wide range of thin film deposition processes. In one approach chemical vapor deposition (CVD, or other related techniques like LPCVD, UHVCVD, DLICVD, AACVD), plasma enhanced CVD (PECVD), a broad range of epitaxial techniques, atomic layer deposition (ALD), or other layer formation techniques can be used.

In either case (or other seed layers) another patterned masking layer 802 (a fourth mask layer) is formed on the seed layer. It is a removable layer 802 with openings in registry with the vias (e.g., 131 of FIG. 7(a)). In some embodiments, resulting interconnects can be used to connect large strings of electrical elements on the single substrate 100. In one example, it can be a photoimageable material such as a photoresist. Such a removable photoresist can be similar to or the same as that used in the first mask layer 101. As before, positive or negative photoresists can be can be applied by any suitable method (e.g., they can be spin coated, roll coated, slit coated, or other suitable process) to form layer 802. The selectively irradiated and developed to form a desired pattern. In one embodiment, a masking layer 802 of photoresist material is generally of a thickness ranging from about 50 μm to about several mm with one preferred embodiment being about 100 μm thick. Again, mask materials can comprise any of the materials disclosed above with respect to mask layer 101 as well as others. The main considerations being relatively good adhesion the seed layer 801.

FIG. 8(b) is a view of the substrate of FIG. 8(a) after further processing. In this embodiment, the portions of the seed layer 801 that are arranged in the openings mask layer 802 are treated to fill 803 the vias 131 with an appropriate material. Commonly, a metal or conductive material is used. For example, Cu, Al, Ti, Ni, or other such materials can be used as the via fill 803 material. In an application where the fill 803 operates as a conductive via, then an electrically conductive material can be used. In this particular embodiment, the fill material can be electroplated onto the seed layer. Other deposition techniques can also be used.

It is also pointed out that for applications where electrical conduction is not required, thermally transmissive non-conductive materials can be used to fill 803 the vias 131 to enable the thermal conduction paths. Example materials can include, but are not limited to nitrides (like CVD deposited diamond, AlN, BN, BeN, or Al₂O₃), potting compounds (like 832C from MG Chemicals and others), or other thermally conducting electrically insulating materials.

To continue, FIG. 8(c) shows the upper portion of the substrate after removal of the mask 802. The seed layer 801 and the fill 803 remain. The fill material 803 in the via 131 can form a surface heat spreader 803a able to distribute heat from the underlying device 121. Thus, excellent heat dissipation properties are provided by the three dimensional heat sink (here, 100, 103, 103, 103a). This large heat dissipation structure enables a great deal of heat to be shunted away from the device 121 from the bottom, sides, and the top, enabling improved heat dissipation, better and faster cooling, increased circuit density, enabling higher operating temperatures and therefore increased device performance. In particular, such enables high device density and the inclusion of heterogeneous devices and elements at extremely close distances and at high circuit densities.

In FIG. 8(d) a cleaning step is used to remove the seed layer 801. An etchant or other process capable of removing the seed layer is used. In one process, a general etching process is used and continues until the seed layer 801 is removed. Since the heat spreader 803a is much thicker than the seed layer 801, a significant heat spreader 803a remains. Thus, the via 131 comprises a contact surface comprising a heat spreader 803a able to distribute heat from the underlying device 121. Thus, excellent heat dissipation properties are provided by the three dimensional heat sink (here, 100, 103, 103, 103a). This large heat dissipation structure enables a great deal of heat to be shunted away from the device 121 enabling improved heat dissipation, better and faster cooling, increased circuit density, enabling higher operating temperatures and therefore increased device performance. In particular, such enables high device density and the inclusion of heterogeneous devices and elements at extremely close distances and at high circuit densities.

A similar process can operate on a substrate such as described in FIG. 7(b). A resulting structure can be configured as in FIG. 8(e), which is a view of the substrate of FIG. 7(b) after further processing. In a process somewhat similar to that described in FIGS. 8(a)-8(d) the vias can be formed and then filled. The exception being that the optional mask layer 111 is simply omitted from the process and layer 140 is formed without need for the underlying layer 111. The openings are made in layer 140 and the contacts (803a, 803b) are made through vias 141. Then all other material (e.g., seed layers, photoresist, etc.) is removed from the top layer.

In one example, a seed layer can be formed on the surface and in the vias in much the same manner as described above or using other processes. A mask layer can them be used such that there are openings in registry with the vias (e.g., 141, 142 of FIG. 7(b)). The thermally and/or electrically conductive material is introduced into the vias 141, 142 until a thermal heat conduction path is formed between the underlying raised portion, via 142, and the surface heat spreader 803b. And also a thermal and/or conductive path is formed between the underlying device 121, via 141, and the surface heat spreader 803a. Materials, dimensions, methods, and processes can be the same as explained above with respect to FIGS. 8(a)-8(d) or using other methodologies.

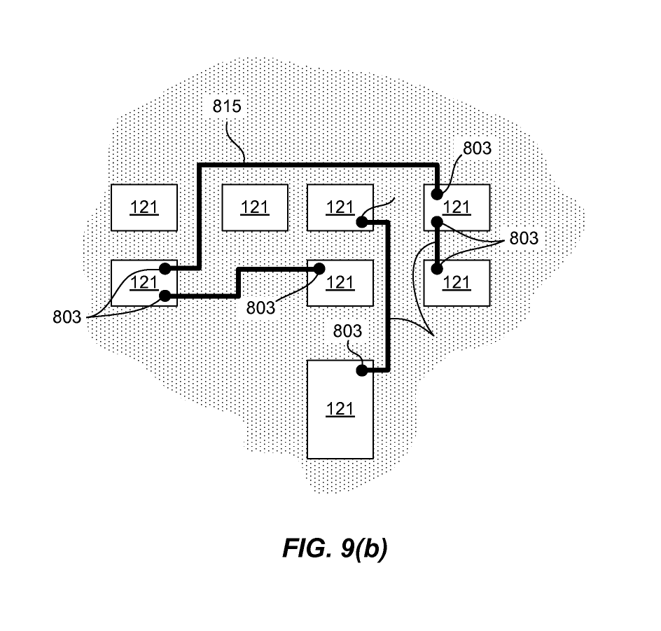

With reference to FIG. 9(a), a portion of a substrate 900 is described. The substrate includes a patterned conductive base element formed as above. Such includes a plurality of recessed device mounting sites 805 arranged between raised portions 803. Devices are coupled with the recessed device mounting sites 805. And a permanent mask layer 806 is formed thereon such that openings (vias 811) are formed in the mask layer 806. The fabrication of the substrate can be conducted with any of the materials and processes described hereinabove as well as others. Material is disposed into the vias 811 using any of an number of different processes. One such embodiment can include the deposition of a seed layer, subsequent masking, then electroplating of metal, and removal of the seed layer, such as described in some of the embodiments above. Many other approaches could also be used.

Additionally, as shown in FIGS. 9(a)-9(b), interconnect structures 815 are arranged between the devices 121. They can be formed on top of the fourth mask layer (e.g., 111) but can also be formed at any level of the substrate. In one example, the same mask and via fill process used to fill the vias can also be used to form the interconnects 815. Similar materials can be used and similar processes can be employed.

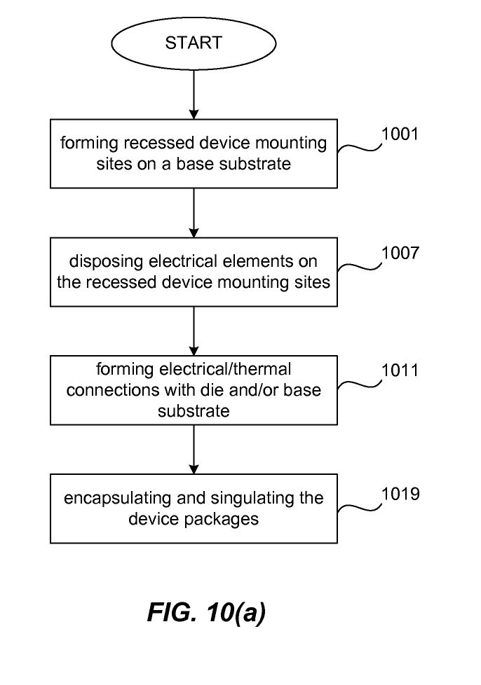

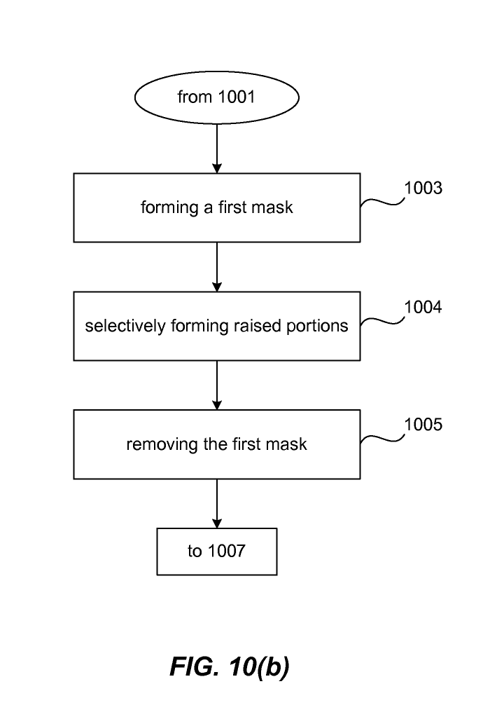

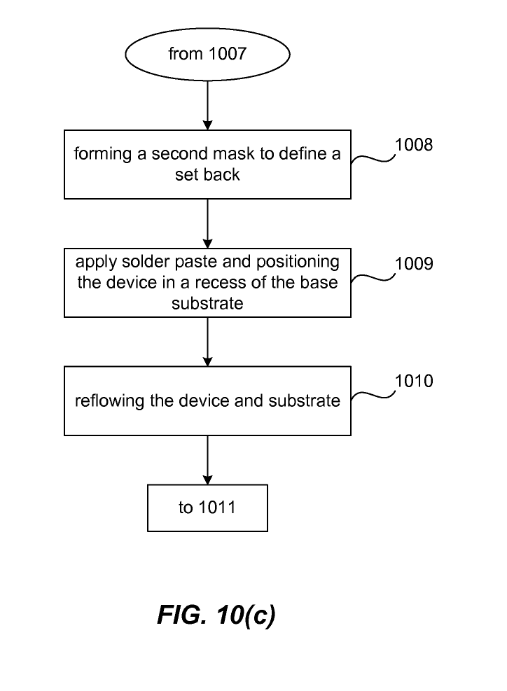

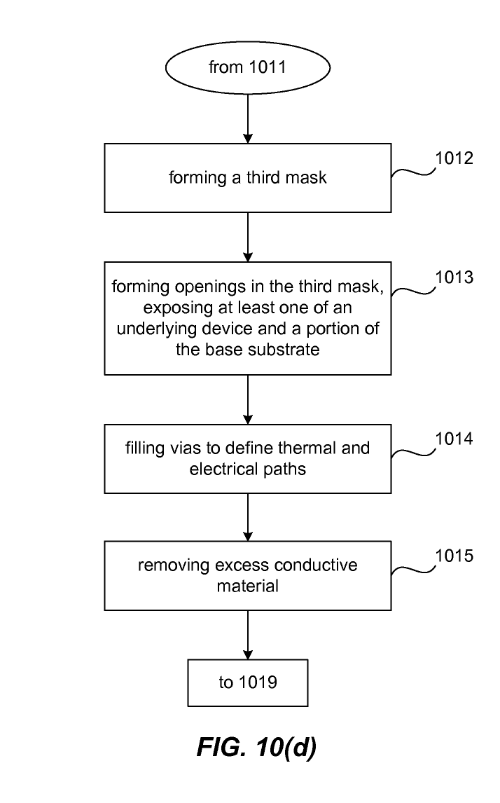

FIG. 10(a) expresses one typical process in accord with the present invention.

A process includes a series of fabrication operations. The process comprises the operation of forming recessed device mounting sites in a base substrate (Step 1001) such that raised portions (relative to the recessed device mounting sites) are arranged about the recessed device mounting sites. Many different modes of fabrication can be used including, but not limited to the operations discussed with respect to FIGS. 1-4, although the invention is expressly not limited to such. This can in fact be a completed product shipped on to end users for further desired processing.

The process comprises the operation of disposing an electrical element in recessed device mounting sites in a base substrate (Step 1007). Many different modes of mounting and fabrication can be used. Examples include, but not limited to the operations discussed with respect to FIGS. 5-6, although the invention is expressly not limited to such and operations can be omitted or added to the process.

The process further comprises the operation of forming at least one of, thermally or electrically, conductive connections with at least one of the substrate of the electrical device and/or the raised portions proximal to the recessed device mounting sites (Step 1011). Many different modes of forming such connections can be used. Examples include, but not limited to the operations discussed with respect to FIGS. 7(a)-9(b), although the invention is expressly not limited to such and operations can be omitted or added to the process.

In a further operation, the assembled embodiments can be encapsulated with a molding material and then cured and singulated to form individual packages (Step 1019).

FIG. 10(b) illustrates one example process of performing the operation of forming recessed device mounting sites in a base substrate (Step 1001) can comprise, forming a first mask on the base substrate that define a fabrication pattern suitable for the formation of recessed portions proximal to associated raised portion (Step 1003). Forming the raised portions by adding conductive material to the base substrate to selectively form the raised portions thereby forming the recessed device mounting sites (Step 1004). Removing the mask from the recessed device mounting sites (Step 1005). Other processes can be used, including those mentioned above, as well as others.

FIG. 10(c) illustrates one example process of performing the operation of disposing the electrical element in the recessed device mounting sites (Step 1007) can further comprise operations described in FIG. 10(b) illustrating disposing a second mask on the substrate to define a set back portion and protect the substrate from various process steps (Step 1008). Solder paste can be applied to at least one of the device or an associated recessed device mounting site and the insertion of the device in the recessed device mounting site (Step 1009). A reflow process is then performed (Step 1010). Additionally, many other modes of mounting and fabrication can be used.

FIG. 10(d) illustrates one example process of forming thermally and/or electrically, conductive connections (Step 1011). The process comprises forming a third mask layer on the substrate (Step 1012). Openings are formed in the third mask layer to form vias that expose at least one of portions of the underlying devices and portions of the underlying base structure (Step 1013). Electrically or thermally conductive materials are used to fill the vias to establish electrical or thermal paths and where desired electrical connections can be established between various devices (Step 1014). Excess conductive material can then be removed (Step 1015). And then as above, once processing is complete, the processed substrate can be encapsulated with a molding material and then cured and singulated to form individual packages (Step 1019).

The inventors point out that many of these process operations can be performed in any order or, alternatively, be performed together. Such packages can exhibit higher device density, shorter interconnect distances, better thermal performance, and superior resulting electrical performance.

The present invention has been particularly shown and described with respect to certain preferred embodiments and specific features thereof. However, it should be noted that the above-described embodiments are intended to describe the principles of the invention, not limit its scope. Therefore, as is readily apparent to those of ordinary skill in the art, various changes and modifications in form and detail may be made without departing from the spirit and scope of the invention as set forth in the appended claims. Other embodiments and variations to the depicted embodiments will be apparent to those skilled in the art and may be made without departing from the spirit and scope of the invention as defined in the following claims. Further, reference in the claims to an element in the singular is not intended to mean “one and only one” unless explicitly stated, but rather, “one or more”. Furthermore, the embodiments illustratively disclosed herein can be practiced without any element which is not specifically disclosed herein. The inventors further indicate that, although process steps, method steps, algorithms or the like may be described in a sequential order, such processes, methods and algorithms may be configured to work in alternate orders. In other words, any sequence or order of steps that may be described in this patent application does not, in and of itself, indicate a requirement that the steps be performed in that order. The steps of described processes may be performed in any order practical. Further, some steps may be performed simultaneously despite being described or implied as occurring non-simultaneously (e.g., because one step is described after the other step). Moreover, the illustration of a process by its depiction in a drawing does not imply that the illustrated process is exclusive of other variations and modifications thereto, does not imply that the illustrated process or any of its steps are necessary to one or more of the invention(s), and does not imply that the illustrated process is preferred.

1. A conductive substrate for electrical device systems, the substrate comprising:
a thermally conductive base element comprising a thermally conductive material; and
the base element including a recessed device mounting site formed thereon, said mounting site suitable for the holding of an electrical device.

2. The conductive substrate recited in claim 1 further comprising a raised portion that defines a sidewall of the recessed device mounting site; and
an electrical device arranged in the recessed device mounting site and in thermal communication with the base element at a bottom surface of the base element and a sidewall of the recessed device mounting site thereby forming a three-dimensional heat sink for the electrical device.

3. The conductive substrate recited in claim 1 wherein the said recessed device mounting site comprises an etched cavity formed in the base element comprising an etched sidewall of said recessed device mounting site.

4. The conductive substrate recited in claim 1 wherein the base element has disposed thereon a second substrate having an opening formed therein, said opening defining said recessed device mounting site such that the second substrate defines a raised sidewall of said recessed device mounting site when the second substrate is disposed on the base element.

5. The conductive substrate recited in claim 2 further comprising,
a protective layer formed over at least a portion of the recessed device mounting site, sidewalls, and the electrical device; and
a first via formed in the protective layer exposing at least one of the device and said sidewall; and
a first interconnect formed in the first via.

6. The conductive substrate recited in claim 5 wherein the interconnect formed in the via comprises at least one of an electrically conducting material and a thermally conducting material.

7. The conductive substrate recited in claim 6 wherein,
the first via comprises one of a plurality of vias;
wherein, the first via exposes the device;
wherein the plurality of vias comprises a second via that exposes at least some of the sidewall; and
a second interconnect formed in the second via.

8. The conductive substrate recited in claim 7 wherein the first interconnect defines a thermal conduction path from the device to a surface of the protective layer.

9. The conductive substrate recited in claim 7 wherein the at least one of the first and the second interconnects defines at least one thermal conduction path from at least one of the device and the raised portion to a surface of the protective layer.

10. The conductive substrate recited in claim 9 wherein the second interconnect defines a thermal conduction path from the raised portion to a surface of the protective layer.

11. The conductive substrate recited in claim 9 wherein the second interconnect defines a thermal conduction path from the raised portion to a surface of the protective layer.

12. The conductive substrate recited in claim 2 wherein the device comprises a vertical transistor device.

13. The conductive substrate recited in claim 2 wherein the device comprises at least one of a passive device or an active device.

14. The conductive substrate recited in claim 2 wherein said recessed device mounting site comprises one of a plurality of such recessed device mounting sites each having an electrical device arranged therein; and
wherein a plurality of these recessed devices are arranged in close physical proximity to adjacent devices on the base element such that three-dimensional heat sink for all of the recessed devices is formed

15. The conductive substrate recited in claim 14 wherein said plurality of recessed devices comprise a plurality of heterogeneous devices arranged such that the base element forms a common three-dimensional heat sink for all of the recessed semiconductor devices.

16. The conductive substrate recited in claim 15 wherein said heterogeneous devices include at least one flash memory device and at least one power convertor.

17-20. (canceled)
